(19) United States
(12) Patent Application Publication
(10) Pub. No.: US 2025/0212537 A1
(43) Pub. Date: Jun. 26, 2025

(54) SOLID-STATE IMAGING DEVICE AND MANUFACTURING METHOD FOR SEMICONDUCTOR DEVICE

(71) Applicant: SONY SEMICONDUCTOR SOLUTIONS CORPORATION, KANAGAWA (JP)

(72) Inventors: HIDEHIRO HARATA, KANAGAWA (JP); KATSUHIKO HANZAWA, KANAGAWA (JP); AKIHIKO KATO, KANAGAWA (JP)

(21) Appl. No.: 18/847,613

(22) PCT Filed: Feb. 2, 2023
(86) PCT No.: PCT/JP2023/003375

§ 371 Date: Sep. 16, 2024

(30) Foreign Application Priority Data
Mar. 24, 2022 (JP) 2022-049059

(51) Int. Cl. H10F 39/00; H04N 25/771; H04N 25/79

(52) U.S. Cl. CPC H10F 39/80373; H04N 25/771; H04N 25/79; H10F 39/011; H10F 39/809

(57) ABSTRACT

A solid-state imaging device efficiently using a three-dimensional transistor. A solid-state imaging device includes a pixel circuit, a pixel array, a first signal line, and a first signal processing circuit. The pixel circuit outputs a signal based on intensity of light received by a light receiving element. In the pixel array, the pixel circuit is arranged in a two-dimensional array in a first direction and a second direction intersecting the first direction. The first signal line is connected to the pixel circuit continuous in the second direction. The first signal processing circuit performs signal processing on a signal from the pixel circuit output from a plurality of the signal lines. Each of at least one transistor in the pixel circuit and at least one transistor in the first signal processing circuit is a three-dimensional transistor.

### TECHNICAL FIELD

The present disclosure relates to a solid-state imaging device and a manufacturing method for a semiconductor device.

### BACKGROUND ART

As a transistor used for a pixel of a complementary metal-oxide-semiconductor field-effect transistor (CMOS) image sensor, there is a transistor in which a high-performance three-dimensional transistor using a recessed channel structure based on a fin field-effect transistor (FinFET) is introduced. By introducing a transistor using a recessed channel structure, noise in a solid-state imaging device can be reduced. Whereas, there is a device that improves performance by using a three-dimensional transistor represented by a FinFET in which a gate is positioned to cover a plurality of surfaces of a channel in an analog circuit of a substrate on which a read circuit of a CMOS image sensor having a multilayer structure is mounted.

By using these techniques in combination, performance can be further improved. However, since a transistor having a three-dimensional structure generally has a complicated structure as compared with a planar-type transistor, the number of wafer process steps for producing tends to increase. As a result, when it is attempted to improve performance by combining the above-described techniques, each number of wafer process steps for forming a three-dimensional transistor such as a recessed channel transistor and a FinFET increases, and a cost increases. Furthermore, there is room for improvement in performance of the read circuit by selectively using a three-dimensional transistor and a conventional planar transistor, but development referring to mounting the three-dimensional transistor and the planar transistor on the same substrate has not been performed much.

### CITATION LIST

### Patent Document

Patent Document 1: Japanese Patent Application Laid-Open No. 2021-034435

### SUMMARY OF THE INVENTION

### Problems to be Solved by the Invention

Therefore, the present disclosure provides a solid-state imaging device in which a three-dimensional transistor and a planar transistor are mixedly mounted and each transistor is efficiently used.

### Solutions to Problems

A solid-state imaging device includes a pixel circuit, a pixel array, a first signal line, and a first signal processing circuit. The pixel circuit outputs a signal based on intensity of light received by a light receiving element. In the pixel array, the pixel circuit is arranged in a two-dimensional array in a first direction and a second direction intersecting the first direction. The first signal line is connected to the pixel circuit continuous in the second direction. The first signal processing circuit performs signal processing on a signal from the pixel circuit output from a plurality of the signal lines. Each of at least one transistor in the pixel circuit and at least one transistor in the first signal processing circuit is a three-dimensional transistor.

The three-dimensional transistor may include a gate electrode including a first vertical gate electrode and a second vertical gate electrode that are embedded in a depth direction from a substrate surface of a semiconductor substrate, each of the first vertical gate electrode and the second vertical gate electrode may have a structure in which a second electrode width at a second depth from the substrate surface is shorter than a first electrode width at a first depth from the substrate surface, the first depth may be a position of a channel uppermost surface of a channel region between the first vertical gate electrode and the second vertical gate electrode, the channel uppermost surface being closest to the substrate surface, the second depth may be a position of a vertical gate electrode bottom surface farthest from the substrate surface in the first vertical gate electrode and the second vertical gate electrode, and directions of the first electrode width and the second electrode width may be same as a direction of a channel width of the channel region.

A negative potential may be applied to a well region of a plurality of the three-dimensional transistors.

The solid-state imaging device may include: a first substrate on which at least the pixel circuit and the first signal processing circuit are formed; and a second substrate on which at least a second signal processing circuit connected to the first signal processing circuit via a second signal line is formed. The first substrate and the second substrate may be stacked to be formed.

The three-dimensional transistor may be formed in the first substrate.

The first signal processing circuit may include a load transistor through which a current according to a bias voltage flows.

The load transistor may be formed by the three-dimensional transistor.

A capacitor connected to a gate of the load transistor may be formed by the three-dimensional transistor.

A transistor that selects a capacitor connected to a gate of the load transistor may be formed by the three-dimensional transistor.

A transistor connected to a gate voltage of the load transistor may be formed by the three-dimensional transistor.

The first signal processing circuit may include a transistor that is connected to the first signal line and forms a differential pair that receives a reference signal and a signal output from the first signal line.

The transistor forming the differential pair may be formed by the three-dimensional transistor.

The first signal processing circuit may include a load transistor that is connected to a transistor forming the differential pair and through which a current according to a bias voltage flows.

The load transistor may be formed by the three-dimensional transistor.

A transistor connected to a gate of the load transistor may be formed by the three-dimensional transistor.

According to an embodiment, in a manufacturing method for a semiconductor device, the semiconductor device includes: a pixel circuit configured to output a signal based on intensity of light received by a light receiving element; a pixel array in which the pixel circuit is arranged in a two-dimensional array in a first direction and a second direction intersecting the first direction; a signal line connected to the pixel circuit continuous in the second direction; and a selector configured to select a signal from the pixel circuit output from a plurality of the signal lines, in which each of at least one transistor in the pixel circuit and at least one transistor in the selector is a three-dimensional transistor, and the manufacturing method includes: forming the three-dimensional transistor in the pixel circuit and the three-dimensional transistor in the selector in the same step.

The three-dimensional transistor may include a gate electrode including a first vertical gate electrode and a second vertical gate electrode that are embedded in a depth direction from a substrate surface of a semiconductor substrate, each of the first vertical gate electrode and the second vertical gate electrode may have a structure in which a second electrode width at a second depth from the substrate surface is shorter than a first electrode width at a first depth from the substrate surface, the first depth may be a position of a channel uppermost surface of a channel region between the first vertical gate electrode and the second vertical gate electrode, the channel uppermost surface being closest to the substrate surface, the second depth may be a position of a vertical gate electrode bottom surface farthest from the substrate surface in the first vertical gate electrode and the second vertical gate electrode, and directions of the first electrode width and the second electrode width may be same as a direction of a channel width of the channel region.

### BRIEF DESCRIPTION OF DRAWINGS

FIG. 1 is a block diagram illustrating an outline of a solid-state imaging device according to an embodiment.

FIG. 2 is a diagram schematically illustrating a configuration of a semiconductor device included in the solid-state imaging element according to an embodiment.

FIG. 3 is a diagram illustrating an example of a structure of a three-dimensional transistor according to an embodiment.

FIG. 4 is a diagram illustrating a part of a circuit of a solid-state imaging device according to an embodiment.

FIG. 5 is a diagram illustrating a part of a circuit of a solid-state imaging device according to an embodiment.

FIG. 6 is a diagram illustrating a part of a circuit of a solid-state imaging device according to an embodiment.

FIG. 7 is a diagram illustrating a part of a circuit of a solid-state imaging device according to an embodiment.

FIG. 8 is a diagram illustrating a part of a circuit of a solid-state imaging device according to an embodiment.

FIG. 9 is a diagram illustrating a part of a circuit of a solid-state imaging device according to an embodiment.

FIG. 10 is a diagram illustrating a part of a circuit of a solid-state imaging device according to an embodiment.

FIG. 11 is a diagram illustrating a part of a circuit of a solid-state imaging device according to an embodiment.

FIG. 12 is a diagram illustrating a part of a circuit of a solid-state imaging device according to an embodiment.

FIG. 13 is a diagram illustrating a part of a circuit of a solid-state imaging device according to an embodiment.

FIG. 14 is a diagram illustrating a part of a circuit of a solid-state imaging device according to an embodiment.

### MODE FOR CARRYING OUT THE INVENTION

The following is a description of embodiments of the present disclosure, with reference to the drawings. The drawings are used for explanation, and the shape and size of each component in actual devices, the ratios of size to other components, and the like are not necessarily as illustrated in the figure. Furthermore, since the drawings are illustrated in a simplified manner, it should be understood that components necessary for implementation other than those illustrated in the figure are provided as appropriate.

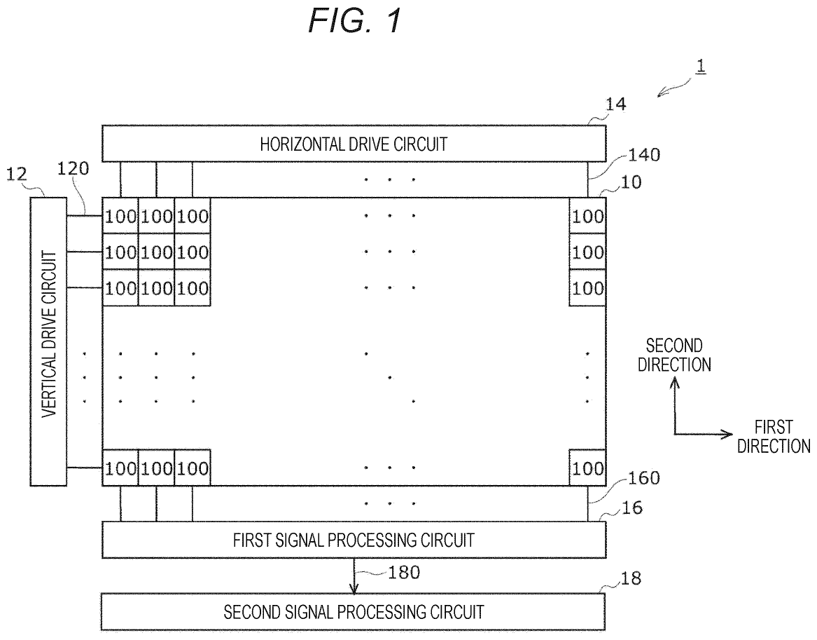

FIG. 1 is a block diagram illustrating an outline of at least a part of a solid-state imaging device 1 according to an embodiment. The solid-state imaging device 1 includes at least a pixel array 10, a vertical drive circuit 12, a horizontal drive circuit 14, a first signal processing circuit 16, and a second signal processing circuit 18. The solid-state imaging device 1 is a device that appropriately converts a signal based on intensity of light received in a light receiving region to acquire image data (or video data, hereinafter, included in the image data).

In addition to this, the solid-state imaging device 1 may include at least one of a control circuit that outputs a signal for controlling each component, a power supply circuit, a storage circuit, or an interface that transmits and receives data to and from outside, in the same semiconductor chip as the components described above. Furthermore, the solid-state imaging device 1 may include a user interface that receives an input from a user or outputs to the user outside the semiconductor chip described above, or may include a network interface for transfer of data to the outside. In the present disclosure, while the components of this paragraph can be optionally mounted on the solid-state imaging device 1, the contents illustrated in FIG. 1 will be mainly described in each embodiment.

The pixel array 10 is a region in which light receiving elements are arranged in an array. The pixel array 10 includes a plurality of pixel circuits 100 arranged in a two-dimensional array in a first direction and a second direction intersecting the first direction. Hereinafter, the first direction may be referred to as a line direction, and the second direction may be referred to as a column direction, but these names are used for convenience and are not limited thereto.

The pixel circuit 100 includes a light receiving element and a circuit element that outputs a signal based on intensity of light received by the light receiving element at an appropriate timing. The output from the pixel circuit 100 is output via a first signal line 160 connected to each of the pixel circuits 100 belonging to the same column. The pixel circuits 100 (the pixel circuits 100 continuous in the first direction) belonging to the same line are connected to the same line direction signal line 120. Similarly, the pixel circuits 100 (the pixel circuits 100 continuous in the second direction) belonging to the same column are connected to the same column direction signal line 140.

The vertical drive circuit 12 selects the pixel circuits 100 belonging to a line in the pixel array 10. The vertical drive circuit 12 selects a line via the line direction signal line 120, drives the pixel circuits 100 belonging to the selected line, and controls the pixel circuits 100 to be in a selected state.

The horizontal drive circuit 14 drives the pixel circuits 100 belonging to a column in the pixel array 10. The horizontal drive circuit 14 drives the pixel circuits 100 belonging to a column via the column direction signal line 140.

The pixel circuit 100 outputs an analog signal according to intensity of received light to the first signal processing circuit 16 via the first signal line 160 in a state of being selected by the vertical drive circuit 12 and in a state of being driven by the horizontal drive circuit 14.

The first signal processing circuit 16 is a circuit that is formed on the same substrate as a substrate on which the pixel circuit 100 is provided, and executes signal processing on a signal output from the pixel circuit 100. The first signal processing circuit 16 acquires the analog signal output from the pixel circuit 100 via the first signal line 160, and executes signal processing on the acquired analog signal.

In the present disclosure, at least one transistor included in the pixel circuit 100 and at least one transistor included in the first signal processing circuit 16 are formed as three-dimensional transistors. In the present disclosure, the three-dimensional transistor refers to a non-planar-type transistor, such as a FinFET or a recessed channel transistor formed by recessing a substrate.

The plurality of three-dimensional transistors can share a well region, for example. Furthermore, a negative potential may be applied in advance to the well region.

The plurality of three-dimensional transistors can be produced in the same step in a semiconductor manufacturing process of forming the components described above. Therefore, in a case of forming a plurality of three-dimensional transistors, it is possible to achieve a semiconductor manufacturing process with the same number of steps as in a case of forming a three-dimensional transistor used for one purpose, as compared with a case of using other transistors.

Details of the three-dimensional transistor and details of a processing circuit of the first signal circuit will be described in individual embodiments.

The second signal processing circuit 18 is a circuit that further executes signal processing on a signal processed by the first signal processing circuit 16. The second signal processing circuit 18 is formed on a semiconductor substrate different from the first signal processing circuit 16. The second signal processing circuit 18 outputs data subjected to appropriate signal processing, to an appropriate circuit such as an image processing circuit, a general-purpose processing circuit, or a machine learning circuit.

As a non-limiting example, an analog signal output from the pixel circuit 100 may be converted into a digital signal in either the first signal processing circuit 16 or the second signal processing circuit 18. As another example, the first signal processing circuit 16 and the second signal processing circuit 18 may each execute a part of processing from an analog signal to a digital signal, and these circuits may cooperatively execute AD conversion.

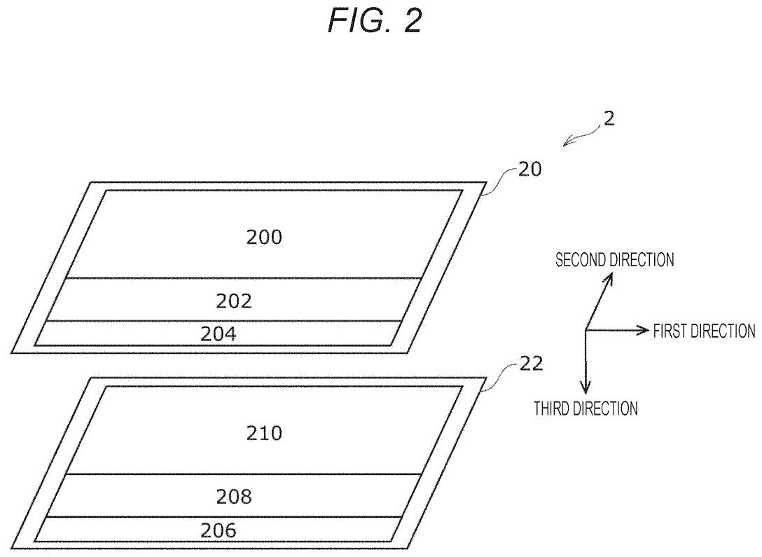

FIG. 2 is a diagram schematically illustrating a non-limiting example of a configuration of a semiconductor chip including at least the pixel array 10, the first signal processing circuit 16, and the second signal processing circuit 18 in the present disclosure.

A semiconductor substrate 2 is a semiconductor chip on which a part of the solid-state imaging device 1 illustrated in FIG. 1 is mounted. The semiconductor substrate 2 includes a first substrate 20 and a second substrate 22. The semiconductor substrate 2 is formed as one semiconductor chip. That is, the semiconductor substrate 2 is a semiconductor device formed as one chip by stacking the first substrate 20 and the second substrate 22 in a third direction intersecting the first direction and the second direction.

The first substrate 20 includes a light receiving region 200, a first signal processing region 202, and a first connection region 204. For example, the first substrate 20 is disposed in the solid-state imaging device 1 so as to be capable of receiving light that has been condensed, transmitted, diffracted, or the like from the outside via an optical system.

The light receiving region 200 is a region in which the pixel array 10 illustrated in FIG. 1 is disposed. That is, individual pixel circuits 100 are arranged in a two-dimensional array in a mode in which a light receiving element can appropriately receive light in the light receiving region 200.

The first signal processing region 202 is a region in which at least the first signal processing circuit 16 illustrated in FIG. 1 is provided. The first signal processing region 202 acquires an analog signal output from the light receiving region 200 via the column direction signal line 140 along the second direction, executes predetermined signal processing on this signal, and outputs the signal.

The first connection region 204 is a region provided with a conductive wire that connects the first substrate 20 and the second substrate 22. The first substrate 20 and the second substrate 22 are connected by, for example, a second signal line 180 illustrated in FIG. 1.

The second substrate 22 includes a second connection region 206, a second signal processing region 208, and a logic circuit region 210.

The second connection region 206 is a region where a signal processed in the first signal processing circuit 16 in the first signal processing region 202 is received on the second substrate 22 side via the first connection region 204 and the second signal line 180.

The second signal processing region 208 is a region in which at least the second signal processing circuit 18 illustrated in FIG. 1 is provided. The second signal processing circuit 18 disposed in the second signal processing region 208 acquires a signal processed in the first signal processing circuit 16 via the second signal line 180, and executes necessary processing.

The logic circuit region 210 includes a logic circuit. This logic circuit is a circuit that performs other various types of signal processing on the signal processed in the first signal processing circuit 16 and the second signal processing circuit 18. For example, the logic circuit may execute image processing on a digital signal of every pixel received in each light receiving pixel to convert the digital signal into an image suitable for output, and may input the image into a learned model to execute acquisition of information regarding the image.

An appropriate circuit is formed in each of the first substrate 20 and the second substrate 22 by a semiconductor process. The semiconductor substrate 2 is formed by stacking the first substrate 20 and the second substrate 22 by using a method of chip on chip (CoC), chip on wafer (CoW), or wafer on wafer (WoW).

The second signal line 180 is appropriately connected between the first connection region 204 and the second connection region 206 by via holes, microbumps, hybrid bonding, or the like. The second signal line 180 may be formed by a conductor of copper, gold, silver, aluminum, or the like between the first substrate 20 and the second substrate 22, by using the above-described technique as a non-limiting example.

Note that the semiconductor substrate 2 in FIG. 2 is illustrated as an example, and the configuration of the semiconductor substrate 2 is not limited to this configuration. For example, a mode may also be adopted in which a third substrate for a storage area provided with a storage circuit is provided between the first substrate 20 and the second substrate 22 or below the second substrate 22 (in a direction opposite to the first substrate 20 in FIG. 2), and the third substrate is also stacked.

From the description of FIGS. 1 and 2, the pixel circuit 100 and the first signal processing circuit 16 are formed on the same first substrate 20. That is, a mode may also be adopted in which the three-dimensional transistors disposed in these circuits are provided only on the first substrate 20.

By dividing a signal processing circuit that processes a signal output from the pixel circuit 100 into the first signal processing circuit 16 and the second signal processing circuit 18 as described above, and disposing a circuit capable of effectively using the three-dimensional transistor in the first signal processing circuit 16, signal processing appropriately using the three-dimensional transistor can be achieved without increasing the steps of the semiconductor process.

For example, in a general CMOS image sensor using a semiconductor chip in which multiple substrates are stacked, a part of a read circuit that reads a signal from a pixel can be cut out as the first signal processing circuit 16 and disposed on a substrate including the pixel. The three-dimensional transistor is superior to a planar-type transistor in characteristics such as an S value, for example.

For this reason, for example, by disposing a circuit configuration that is to be greatly affected by switching performance and a leakage current on the same substrate as the pixel, a three-dimensional transistor can be used as an appropriate constituent element, and a mode in which the semiconductor process steps are not increased can be obtained.

Furthermore, unlike a planar type in which a gate is horizontally formed on an upper surface of a semiconductor substrate, a gate is formed in a vertical direction in the three-dimensional transistor. For this reason, in a case where the semiconductor substrate has a height of a general semiconductor substrate capable of sufficiently exhibiting gate performance, an area for forming the transistor can be reduced, which results in achievement of reduction of an area of the entire circuit.

However, the example described above does not exclude a mode in which the three-dimensional transistor is provided also in the second substrate 22.

Next, a three-dimensional transistor will be described.

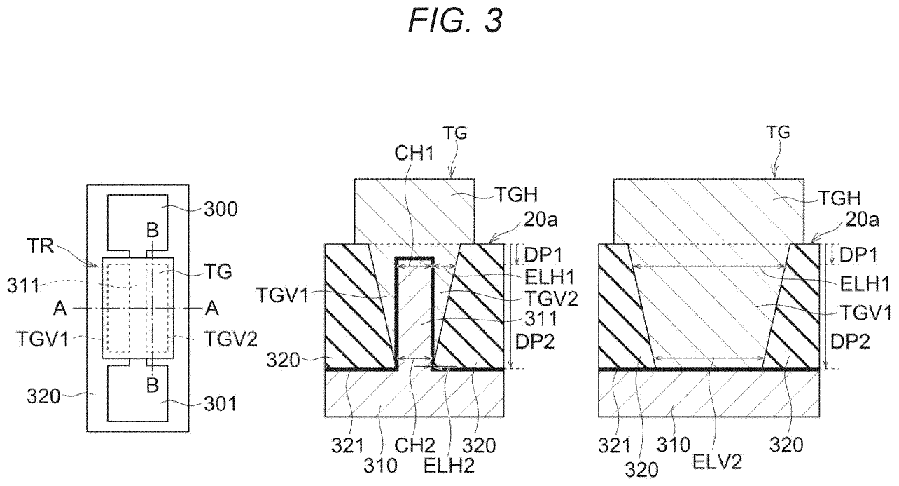

FIG. 3 is a diagram illustrating an example of a three-dimensional transistor according to an embodiment. The drawing illustrates, in order from the left, a plan view of a three-dimensional transistor TR, an A-A cross-sectional view of the three-dimensional transistor TR in the plan view, and a B-B cross-sectional view of the three-dimensional transistor TR in the plan view.

In the plan view, a gate electrode TG of the three-dimensional transistor TR is disposed between a high-concentration n-type layer 300 as a drain and a high-concentration n-type layer 301 as a source.

As illustrated in the A-A cross-sectional view and the B-B cross-sectional view, the gate electrode TG of the three-dimensional transistor TR includes: a planar electrode portion TGH on an upper side of a first surface 20a (substrate surface) of the first substrate 20; and a first vertical gate electrode TGV1 and a second vertical gate electrode TGV2 which are embedded in a depth direction from the first surface 20a. The first vertical gate electrode TGV1 and the second vertical gate electrode TGV2 may be simply referred to as vertical gate electrodes TGV in a case of being not particularly distinguished from each other.

In the A-A cross-sectional view, a fin portion 311 serving as a channel region of the three-dimensional transistor TR is formed by a p-well 310 between the first vertical gate electrode TGV1 and the second vertical gate electrode TGV2. Note that, in this configuration example, the fin portion 311 is formed by the p-well 310, but the fin portion 311 may be formed by a region of the first substrate 20 where ion implantation is not performed.

An outer direction of the first vertical gate electrode TGV1 and the second vertical gate electrode TGV2 is surrounded by an insulating film 320 including an oxide film. Between the fin portion 311 serving as the channel region and the first vertical gate electrode TGV1 and the second vertical gate electrode TGV2, an oxide film 321 is formed as a gate oxide film of the three-dimensional transistor TR. The oxide film 321 is also formed between the insulating film 320 and the p-well 310.

In the A-A cross-sectional view, each of the first vertical gate electrode TGV1 and the second vertical gate electrode TGV2 has a structure in which a second electrode width ELH2 at a second depth DP2 from the first surface 20a is shorter than a first electrode width ELH1 at a first depth DP1 from the first surface 20a. In other words, the first vertical gate electrode TGV1 and the second vertical gate electrode TGV2 have a reverse tapered shape in which a bottom surface (a second surface opposite to the first surface 20a) side of the vertical gate electrode TGV is narrow in the cross-sectional view.

Whereas, in the fin portion 311 serving as the channel region, a first channel width CH1 at the first depth DP1 from the first surface 20a and a second channel width CH2 at the second depth DP2 from the first surface 20a are the same or substantially the same. Here, “substantially the same” represents a range of difference that can be regarded as the same, and deviation due to a manufacturing error or the like is included in “substantially the same”.

Here, the first depth DP1 is a position of an uppermost surface of a channel closest to the first surface 20a in the fin portion 311 between a second vertical gate electrode AGV1 and a second vertical gate electrode AGV2, and the second depth DP2 is a position of a bottom surface of a vertical gate electrode AGV farthest from the first surface 20a in the first vertical gate electrode AGV1 and the second vertical gate electrode AGV2. Note that, in the drawing, priority is given to visibility, and the positions are shifted to an extent.

Also in the B-B cross-sectional view, each of the first vertical gate electrode AGV1 and the second vertical gate electrode AGV2 has a structure in which a second electrode width ELV2 at the second depth DP2 from the first surface 20a is shorter than a first electrode width ELV1 at the first depth DP1 from the first surface 20a. In other words, the first vertical gate electrode AGV1 and the second vertical gate electrode AGV2 have a reverse tapered shape in which a bottom surface side of the vertical gate electrode AGV is narrow in the cross-sectional view.

As described above, the three-dimensional transistor TR may have a FinFET structure in which the fin portion 311 constituting the channel region is sandwiched between the first vertical gate electrode AGV1 and the second vertical gate electrode AGV2 which are embedded in the depth direction from the first surface 20a of the first substrate 20.

Each of the first vertical gate electrode AGV1 and the second vertical gate electrode AGV2 has a reverse tapered shape with a narrow bottom surface side, and a contact area with the p-well 310 is reduced, so that a parasitic capacitance can be reduced. Since the parasitic capacitance can be reduced, noise generated in the three-dimensional transistor TR can be reduced, and a signal to noise ratio (S/N ratio) can be improved.

Hereinafter, with a non-limiting example, a description will be given to mounting of the three-dimensional transistor in the pixel circuit 100 illustrated in FIG. 1 and disposition of components and mounting of the three-dimensional transistor in the first signal processing circuit 16 and the second signal processing circuit 18, in the semiconductor substrate 2 illustrated in FIG. 2. As described above, switching performance and the like can be improved and a disposition area of transistors can be reduced by the plurality of three-dimensional transistors mounted on the first substrate 20.

Furthermore, in a case of forming a plurality of three-dimensional transistors in the first substrate 20, the plurality of three-dimensional transistors can be formed at the same timing (the same step) in the same semiconductor manufacturing process. That is, the first substrate 20 can be formed with substantially the same number of steps as a case where the pixel circuit 100 includes the three-dimensional transistor while the second substrate 22 includes other transistor. Therefore, a manufacturing cost of the semiconductor chip can be reduced.

Furthermore, in the first signal processing circuit 16, by adopting a mode capable of outputting with a smaller number of signal lines than the number of the first signal lines 160, that is, making the number of the second signal lines 180 smaller than the number of the first signal lines 160, it is also possible to reduce the number of signal lines between the stacked first substrate 20 and second substrate 22.

Note that, for example, in a case of forming the three-dimensional transistor as an n-type MOSFET, a negative potential is applied to the well region. Furthermore, in a case of forming a plurality of three-dimensional transistors, at least some of the three-dimensional transistors may share the well region.

Note that, as described up to FIG. 2, FIG. 3 illustrates a FinFET as a non-limiting example of the three-dimensional transistor, and the three-dimensional transistor in the present disclosure can also include a transistor that is not a planar type and is formed three-dimensionally, such as a recessed channel transistor other than the FinFET.

### First Embodiment

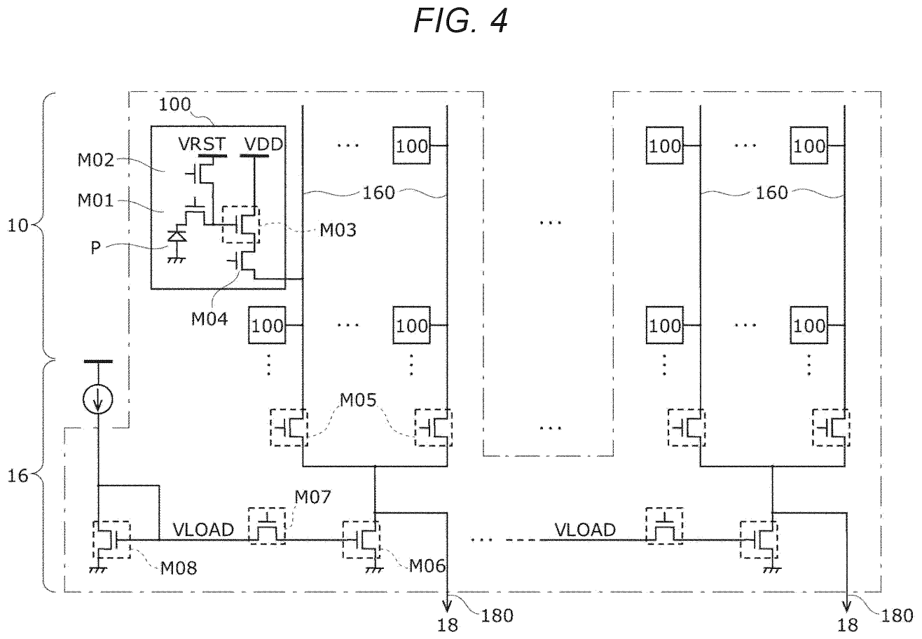

FIG. 4 is a diagram illustrating a part of a circuit of a solid-state imaging device 1 according to an embodiment. FIG. 4 illustrates a pixel circuit 100 and a first signal processing circuit 16. A configuration surrounded by a one-dot chain line is disposed on a first substrate 20.

As a non-limiting example, the pixel circuit 100 includes a light receiving element P and transistors M01, M02, M03, and M04 as illustrated in the figure. Note that, in the figure, a circuit example is illustrated for one pixel circuit 100, but equivalent circuits are disposed in principle also for other pixel circuits 100.

The light receiving element P is, for example, an element that causes a current to flow on the basis of received light intensity of a photodiode or the like. The light receiving element P has an anode grounded and a cathode connected to a drain of the transistor M01.

The transistor M01 is, for example, an n-type MOSFET, and has the drain connected to the cathode of the light receiving element P and a source connected to a floating region. The transistor M01 operates as a transfer transistor that transfers a drain current based on an output from the light receiving element P to the floating region. An appropriate voltage is applied to a gate of the transistor M01 on the basis of a transfer timing, and a charge is transferred from the light receiving element P to the floating region at an appropriate timing.

The transistor M02 is, for example, an n-type MOSFET, and is connected between a predetermined reset potential VRST and the floating region. The transistor M02 operates as a reset transistor that initializes a charge accumulated in the floating region at a timing after outputting to the outside of the pixel circuit 100 and before transferring an output from the light receiving element P. A voltage for controlling this reset is applied to a gate of the transistor M02, and a charge of the floating region is reset at a timing of turning on.

The transistor M03 is, for example, an n-type MOSFET, and has a gate connected to the floating region, a drain connected to a predetermined image power supply voltage VDD, and a source connected to a drain of the transistor M04. The transistor M03 operates as an amplification transistor that amplifies and outputs a voltage based on a charge accumulated in the floating region.

The transistor M04 is, for example, an n-type MOSFET, and has a gate connected to the line direction signal line 120, the drain connected to the source of the transistor M03, and a source connected to a first signal line 160. The pixel circuit 100 transmits a signal based on a potential applied to the drain to the first signal line 160 on the basis of a voltage applied to the transistor M04 in accordance with an output from the vertical drive circuit 12.

In accordance with the above, the pixel circuit 100 outputs a signal based on intensity of light received by the light receiving element P to the first signal line 160.

Note that the pixel circuit 100 described above is illustrated as a very simple example, and is not limited to this configuration.

Next, the first signal processing circuit 16 will be described. As a non-limiting example, the first signal processing circuit 16 includes transistors M05, M06, M07, and M08. As a non-limiting example, the first signal processing circuit 16 is a circuit that selectively performs signal processing on signals input from a plurality of first signal lines 160 and outputs the signals.

The transistor M05 is, for example, an n-type MOSFET, and has a drain connected to the first signal line 160 and a gate connected to the column direction signal line 140. The transistor M05 is a transistor that is provided for every first signal line 160 and controls output of a signal propagated through the first signal line 160. The plurality of transistors M05 shares a source and outputs signals from the pixel circuits 100 belonging to a column selected on the basis of the control from the horizontal drive circuit 14.

The transistor M06 is, for example, an n-type MOSFET, and has a drain connected to the source of the transistor M05, a source grounded, and a gate connected to a source of the transistor M07. The transistor M06 operates as a load transistor that causes a load current to flow on the basis of a bias voltage applied to the gate. The transistor M06 operates as a constant current source that causes a current based on a current flowing through a drain of the transistor M08 to flow as a load current.

The transistor M07 is, for example, an n-type MOSFET, and has a drain connected to the current source and the source connected to the gate of the transistor M06. The transistor M07 is a transistor that generates a bias voltage to be applied to the gate of the transistor M06 on the basis of a current input from the current source.

The transistor M08 is, for example, an n-type MOSFET, and has the drain connected to a constant current source, a source grounded, and a gate connected to the drain. The transistor M08 forms a current mirror with the transistor M06, and a drain current of the transistor M06 is determined on the basis of a drain current of the transistor M08. It suffices that at least one transistor M08 is provided for the plurality of transistors M06.

Note that the constant current source connected to the drain of the transistor M08 is not included in the first signal processing circuit 16, that is, may be disposed on a second substrate 22 instead of the first substrate 20.

By using the transistor M06 as a load transistor, as described above, a signal from the pixel circuit 100 controlled by the vertical drive circuit 12 and the horizontal drive circuit 14 can be selectively output to a second signal processing circuit 18 via a second signal line 180. By configuring the circuit in this manner, transmission of a signal from the first substrate 20 to the second substrate 22 can be achieved with fewer paths than the first signal lines 160.

In an embodiment, the transistors surrounded by dotted lines can be formed as three-dimensional transistors. For example, in FIG. 4, the transistors M03, M05, M06, M07, and M08 can be formed as three-dimensional transistors. These transistors are transistors required to have switching performance. Therefore, it is desirable to form as three-dimensional transistors.

More specifically, the load transistor (transistor M06) and the transistor M07 to which a gate voltage of the load transistor is applied may be formed as three-dimensional transistors.

According to the present embodiment, the transistors required to have switching performance can be appropriately made three-dimensional transistors, and these three-dimensional transistors can be formed in one substrate. As a result, it is possible to secure appropriate switching performance without increasing a manufacturing process, that is, without increasing a manufacturing cost and while reducing a circuit area.

Also in drawings of the following embodiments, three-dimensional transistors are represented by transistors surrounded by dotted lines.

### Second Embodiment

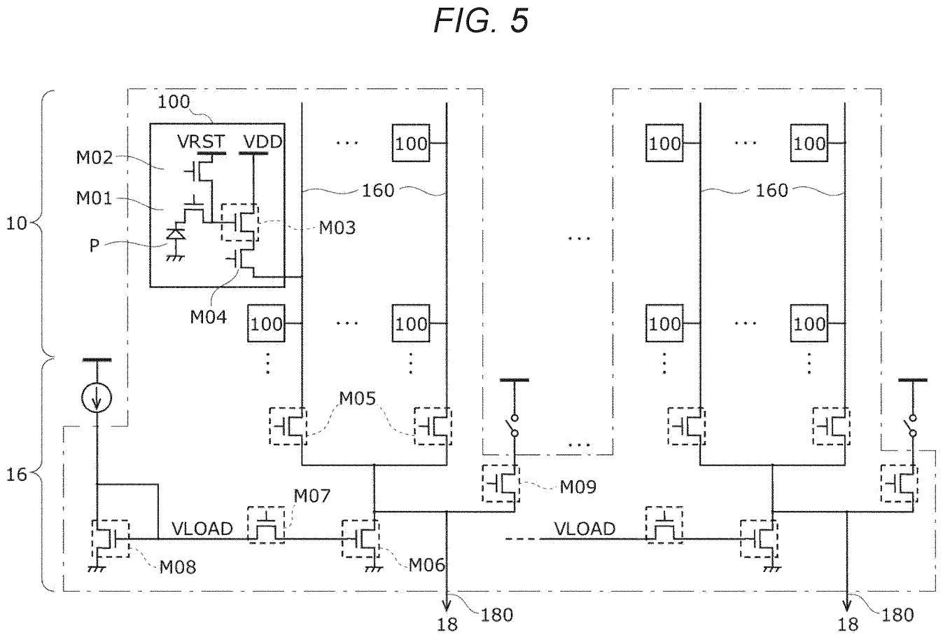

FIG. 5 is a diagram illustrating a part of a circuit of a solid-state imaging device 1 according to an embodiment. This FIG. 5 illustrates a pixel circuit 100 and a first signal processing circuit 16. A configuration surrounded by a one-dot chain line is disposed on a first substrate 20.

In addition to the first embodiment described above, in the present embodiment, a black spot correction circuit is further incorporated in the configuration. The first signal processing circuit 16 further includes a transistor M09 that performs black spot correction, in addition to the components of the first embodiment.

The transistor M09 is, for example, an n-type MOSFET, and has a drain connected to a predetermined voltage via a switch and a source connected to a source of a transistor M05. The transistor M09 is a transistor that sets a control voltage to an appropriate value when leakage of charges due to sunlight occurs and a reset voltage in a reset period in correlated double sampling (CDS) or the like is controlled to be low.

An appropriate voltage is applied to a gate of the transistor M09 at a timing when black spot correction is required, and an appropriate reset voltage subjected to black spot correction is output to an AD conversion circuit provided in a second signal processing circuit 18 via a second signal line 180. The timing at which the black spot correction is required can be determined similarly to a general black spot correction circuit.

This black spot correction transistor can be further formed as a three-dimensional transistor. As described above, according to the present embodiment, by forming the three-dimensional transistor having excellent switching performance as the black spot correction transistor in the first substrate 20, it is possible to appropriately perform the black spot correction in the vicinity of a threshold, avoid an increase in a manufacturing process, and reduce a circuit area.

### Third Embodiment

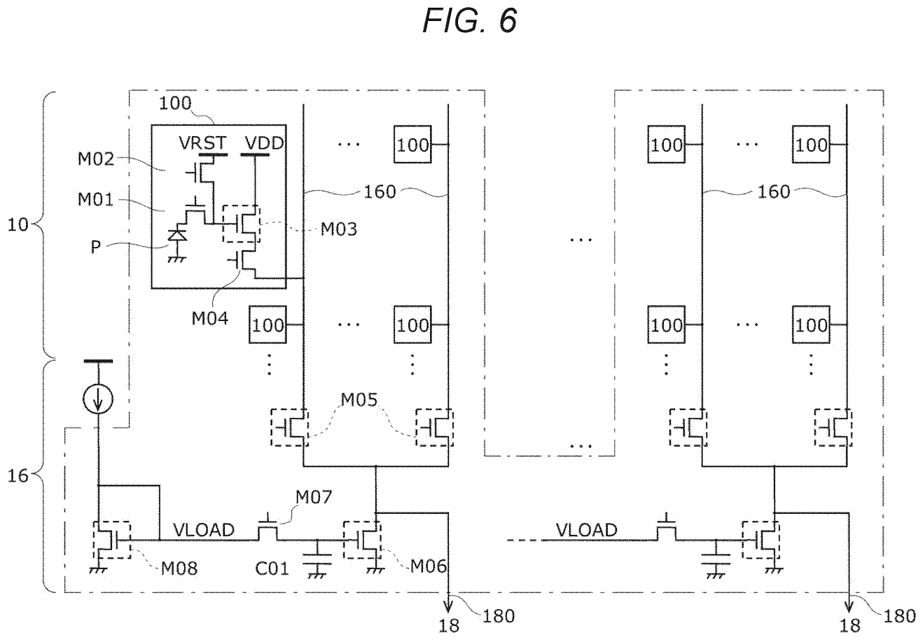

FIG. 6 is a diagram illustrating a part of a circuit of a solid-state imaging device 1 according to an embodiment. FIG. 6 illustrates a pixel circuit 100 and a first signal processing circuit 16. A configuration surrounded by a one-dot chain line is disposed on a first substrate 20.

In addition to the first embodiment described above, in the present embodiment, a sample-and-hold circuit is provided in a path for application to a gate of a transistor M06. The sample-and-hold circuit includes, for example, a transistor M07 and a capacitor C01.

Also in such a mode, a three-dimensional transistor can be appropriately used. According to the configuration of FIG. 6, it is possible to improve random telegraph noise (RTS noise) by using a three-dimensional transistor as a constant current source.

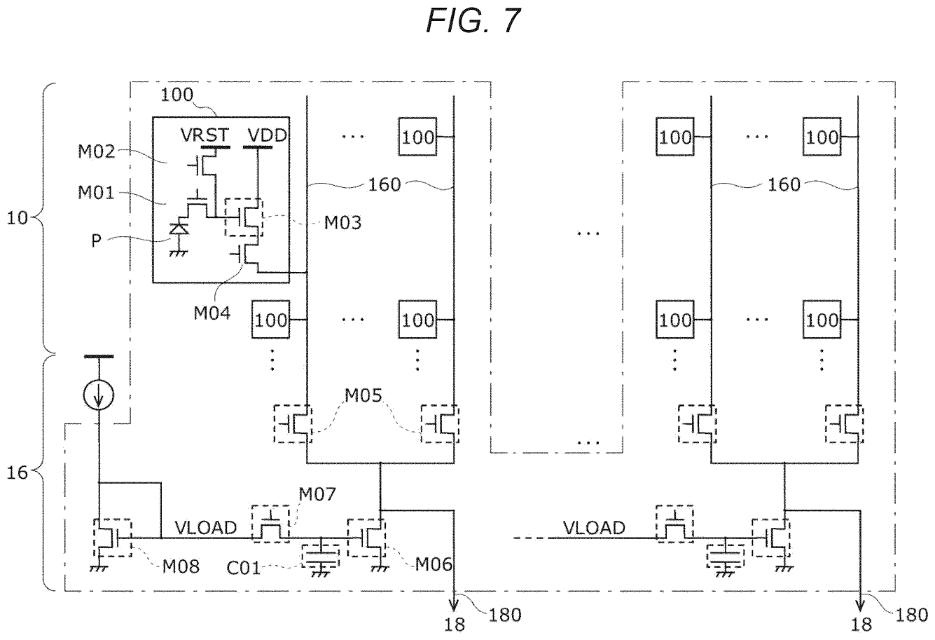

Note that, as illustrated in FIG. 7, the transistor M07 forming the sample-and-hold circuit may be a three-dimensional transistor. In this case, the capacitor C01 can also be formed using a three-dimensional transistor. The capacitor C01 can be formed in the same step as other three-dimensional transistors. Furthermore, at least one of the transistor M07 or the capacitor C01 may be formed using a three-dimensional transistor.

In this configuration, the transistors M06, M07, and M08 and the capacitor C01 can be formed as three-dimensional transistors sharing a well. By forming in this manner, RTS noise can be improved. Furthermore, it is also possible to reduce a circuit area in each case.

Also in the cases of FIGS. 6 and 7, similarly to FIG. 5, a black spot correction circuit may be further included in the first signal processing circuit 16.

### Fourth Embodiment

According to each of the above-described embodiments, a configuration is adopted in which the first signal processing circuit 16 includes the signal processing circuit from the pixel circuit 100, but the mode of the present disclosure is not limited to such a mode. The first signal processing circuit 16 may further include a comparison circuit that is for processing before AD conversion.

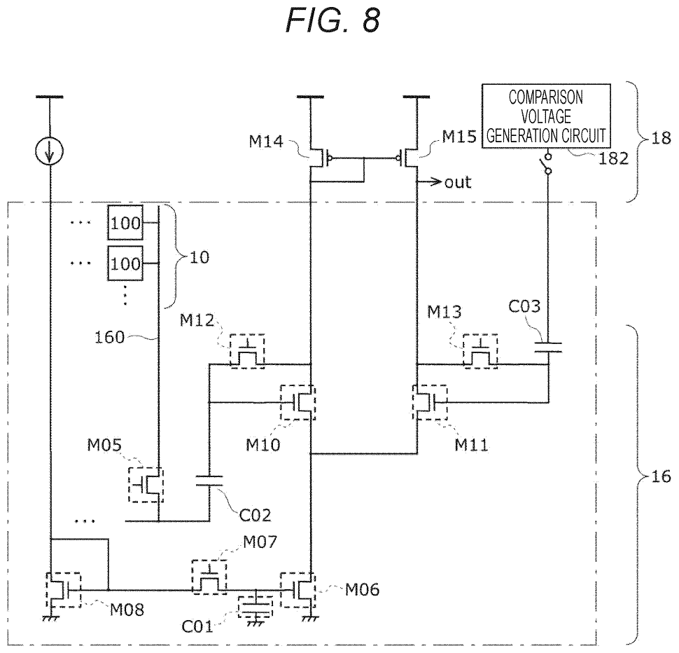

FIG. 8 is a diagram illustrating a part of a circuit of a solid-state imaging device 1 according to an embodiment. FIG. 8 illustrates at least a part of a pixel circuit 100, the first signal processing circuit 16, and a second signal processing circuit 18. A configuration surrounded by a one-dot chain line is disposed on a first substrate 20.

As compared with the above-described individual embodiments, the first signal processing circuit 16 further includes capacitors C02 and C03, and transistors M10, M11, M12, and M13, which are formed as a part of the comparison circuit. The first signal processing circuit 16 may further include a black spot correction circuit.

The capacitor C02 accumulates a voltage proportional to a signal output from the pixel circuit 100. The capacitor C02 has one end connected to a source of a transistor M05 and another end connected to a gate of the transistor M10 and a source of the transistor M12.

The capacitor C03 accumulates a voltage proportional to a comparison voltage (a reference voltage with respect to an output from the pixel circuit) output from a comparison voltage generation circuit 182 included in a second substrate 22. One end is connected to the comparison voltage generation circuit provided in the second substrate 22 via a switch, and another end is connected to a gate of the transistor M11 and a source of the transistor M13.

The transistor M10 is, for example, an n-type MOSFET, and has the gate connected to the capacitor C02, a drain connected to a drain of a transistor M14, and a source connected to a drain of a transistor M06.

The transistor M11 is, for example, an n-type MOSFET, and has the gate connected to the capacitor C03, a drain connected to a drain of a transistor M15, and a source connected to the source of the transistor M10 and the drain of the transistor M06.

These transistors M10 and M11 are transistors that operate as a differential pair that receives a differential input. That is, the transistors M10 and M11 operate as a differential pair that outputs a difference between a signal from a first signal line connected to the gate of the transistor M10 and a comparison voltage output from the comparison voltage generation circuit 182.

The transistor M12 is, for example, an n-type MOSFET, and has the drain connected to the drain of the transistor M10, the source connected to the gate of the transistor M10, and a gate to which a voltage controlled by a reset timing is applied.

The transistor M13 is, for example, an n-type MOSFET, and has a drain connected to the drain of the transistor M11, the source connected to the gate of the transistor M11, and a gate to which a voltage controlled at the same timing as that of the transistor M12 is applied.

The transistor M12 and the transistor M13 operate as switches that initialize voltages of the gates of the transistor M10 and the transistor M11, that is, carriers accumulated in the capacitor C02 and the capacitor C03, respectively. For example, at a timing at which AD conversion is performed in the second signal processing circuit 18 in the subsequent stage, these transistors M12 and M13 appropriately execute discharge of the capacitors C02 and C03 before a reset period and discharge of the capacitors C02 and C03 before a data reading period, on the basis of a timing signal applied to the gate.

As illustrated in the figure, the capacitors C02 and C03, the transistors M10, M11, M12, and M13 may be formed in the first signal processing circuit 16 in the first substrate 20 as a non-limiting example.

Signals output from the drain of the transistor M10 and the drain of the transistor M11 are output to the drain of the transistor M14 and the drain of the transistor M15 provided in the second substrate 22, respectively.

The transistor M14 is, for example, a p-type MOSFET, and has the drain connected to the drain of the transistor M10, a source connected to a power supply voltage, and a gate connected to the drain.

The transistor M15 is, for example, a p-type MOSFET, and has the drain connected to the drain of the transistor M11, a source connected to a power supply voltage, and a gate connected to the gate of the transistor M14.

The transistors M14 and M15 constitute a current mirror, and output a voltage according to a difference between signals applied to the gate of the transistor M10 and the gate of the transistor M11 from the drain (“out” in the figure) of the transistor M15. The output signal is input to a timing counter and used for conversion into a digital signal.

In FIG. 8, as a non-limiting example, the transistor M10 and the transistor M11 forming a differential pair may be formed as three-dimensional transistors. Furthermore, the transistor M12 and the transistor M13 for initializing these transistors may be similarly formed as three-dimensional transistors.

By forming the signal processing circuit using the three-dimensional transistor as described above, it is possible to improve RTS noise in the transistors M10 and M11 on the input side, and it is possible to reduce a circuit area in the transistors M12 and M13.

Similarly to the above-described embodiments, the transistor M06 which is a load transistor in which a load current according to a bias voltage flows and which operates as a constant current source may also be formed as a three-dimensional transistor.

Moreover, similarly to the above-described embodiments, three-dimensional transistors may also be optionally used as transistors M07 and M08 connected to the gate of the transistor M06 and the capacitor C01 operating as the sample-and-hold circuit.

In FIG. 8, the transistors M10, M11, M12, and M13 may be formed to share a well region.

### Other Implementation Examples

Hereinafter, some implementation examples will be described regarding disposition of three-dimensional transistors and well sharing of the plurality of three-dimensional transistors. Although only one pixel circuit 100 is illustrated in the drawings used for description for ease of understanding, a plurality of pixel circuits 100 is provided, and the circuits illustrated in the drawing are appropriately arranged in parallel to constitute a signal processing circuit or the like, similarly to the above-described embodiments. Furthermore, although the configuration is described in which the comparator described with reference to FIG. 8 is not provided, it should be noted that the comparator can be optionally provided in a similar configuration.

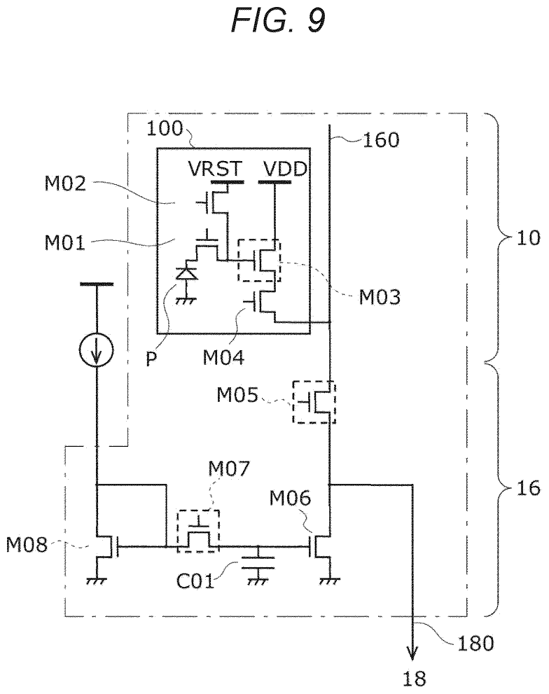

In the example of FIG. 9, a transistor M03 which is an amplification transistor and a transistor M07 which switches a bias voltage are formed as three-dimensional transistors. By forming the transistor M07 which switches the bias voltage as a three-dimensional transistor, a circuit area can be significantly reduced as compared with a case where the transistor M07 is formed by a planar-type transistor.

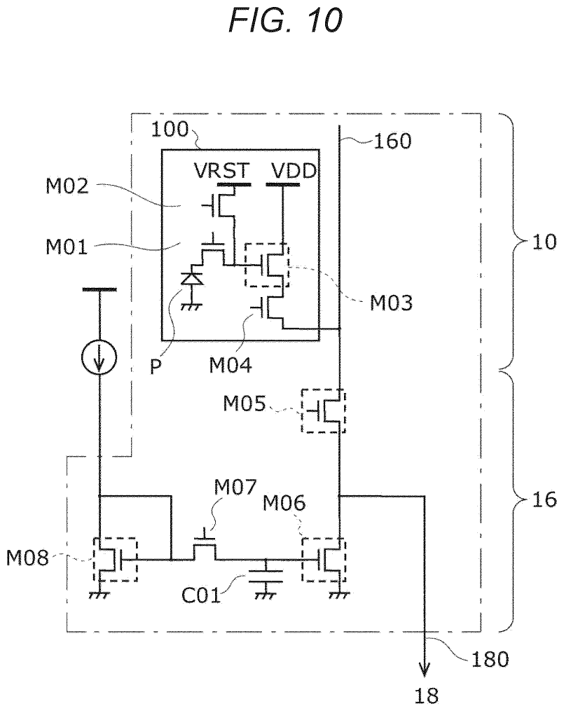

In the example of FIG. 10, a transistor M03 which is an amplification transistor, a transistor M06 which is a load transistor, and a transistor M08 which generates a bias voltage to be applied to a gate of the transistor M06 are formed as three-dimensional transistors. By forming the three-dimensional transistors in this manner, it is possible to improve RTS noise due to a current output from a constant current source of the second substrate 22, in a generation transistor and a load transistor of the bias voltage.

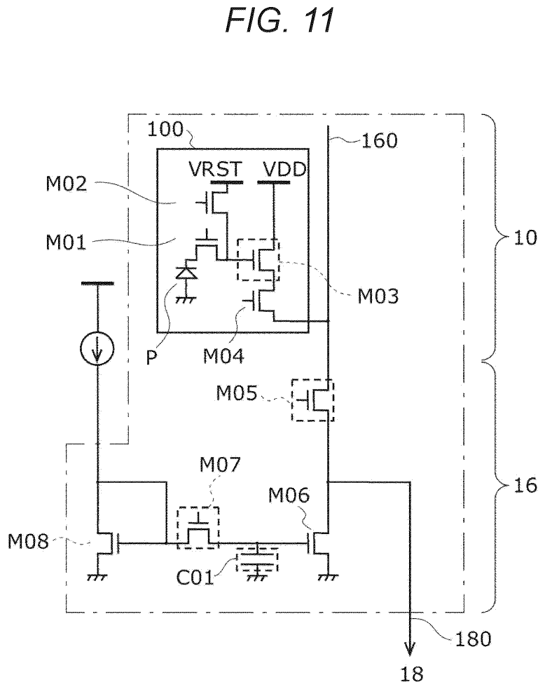

In the example of FIG. 11, a transistor M03 which is an amplification transistor, a transistor M07 constituting a sample-and-hold circuit, and a capacitor C01 are formed as three-dimensional transistors. The transistor M07 and the capacitor C01 may be formed to share a well region of the three-dimensional transistors.

By forming the three-dimensional transistors in this manner, a sample-and-hold circuit for a bias voltage of a load transistor can be formed by the three-dimensional transistor. As a result, a circuit area can be reduced.

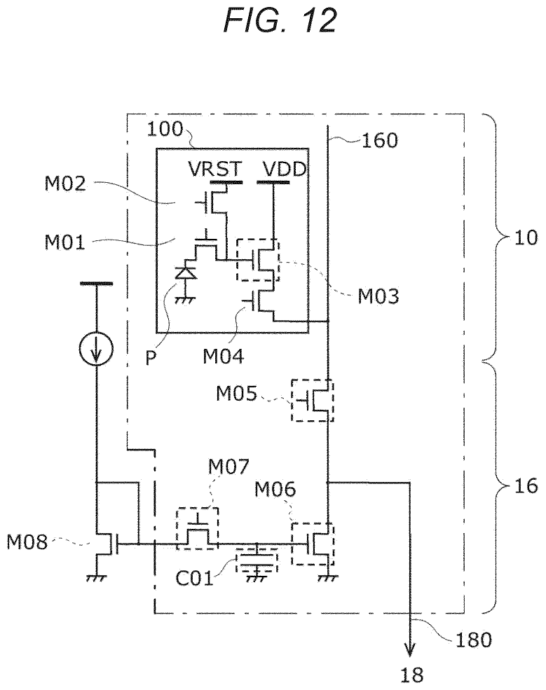

In the example of FIG. 12, a transistor M03 which is an amplification transistor, a transistor M06 which is a load transistor, a transistor M07 constituting a sample-and-hold circuit, and a capacitor C01 are formed as three-dimensional transistors. The transistors M06 and M07 and the capacitor C01 can be formed to share a well region. Furthermore, a transistor M08 which generates a bias voltage from a constant current source is provided not in the first substrate 20 but in the second substrate 22.

By forming the three-dimensional transistors in this manner, it is possible to reduce a circuit area and improve RTS noise. Note that, forming the transistor M08 not in the first signal processing circuit 16 but in the second substrate 22, for example, the second signal processing circuit 18 can be similarly applied to other embodiments and implementation examples.

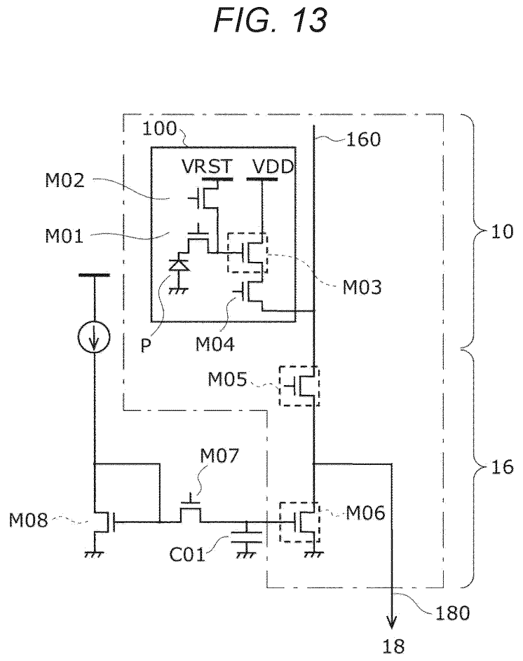

In the example of FIG. 13, a transistor M03 which is an amplification transistor and a transistor M06 which is a load transistor are formed as three-dimensional transistors. A transistor M08 which generates a bias voltage to be applied to a gate of the transistor M06, a transistor M07 constituting a sample-and-hold circuit, and a capacitor C01 are provided not in the first substrate 20 but in the second substrate 22.

By forming the load transistor as a three-dimensional transistor, a circuit area can be reduced.

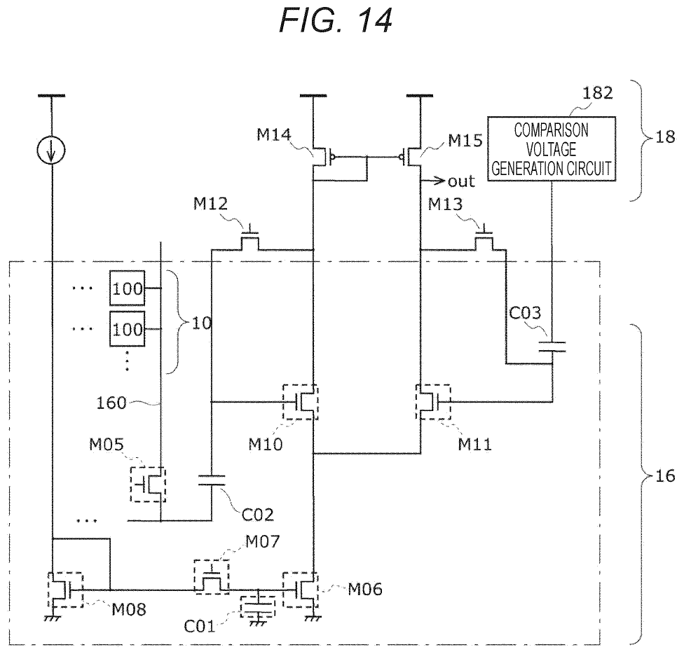

In the example of FIG. 14, a part of the comparator illustrated in FIG. 8 is provided in the first signal processing circuit 16, and other part is provided in the second signal processing circuit 18. Transistors M10 and M11 may be formed so as to share a well region in the first substrate 20. As described above, a mode may also be adopted in which a differential pair is formed in the first signal processing circuit 16, that is, the first substrate 20, and a current mirror is formed in the second signal processing circuit 18, that is, the second substrate 22.

Which one of the transistors formed on the first substrate 20 is made as the three-dimensional transistor can be considered similarly to each of the above-described implementation examples. Furthermore, as illustrated in FIGS. 12 and 13, at least some of transistors and capacitors constituting a constant current source may be formed on the second substrate 22.

According to each of the embodiments described above, for example, any transistor can be formed as a three-dimensional transistor by the same manufacturing process as a case of forming an amplification transistor as a three-dimensional transistor in a pixel circuit. Therefore, by forming at least one of transistors constituting a circuit that reads a signal from the pixel circuit into a digital signal on the same substrate as a substrate on which the pixel circuit is provided, a circuit area can be reduced and switching performance can be improved without increasing a manufacturing process and a cost.

Furthermore, by forming as a three-dimensional transistor, RTS noise can be improved in an appropriate transistor. In a case where a part of a solid-state imaging device is formed as a multilayer semiconductor device, by disposing at least a circuit for selecting an output from a pixel circuit on a substrate on the pixel circuit side, it is also possible to achieve connection between layers with signal lines less than output lines from the pixel circuit.

The embodiments described above may have the following modes.

(1)

A solid-state imaging device including:
a pixel circuit configured to output a signal based on intensity of light received by a light receiving element;
a pixel array in which the pixel circuit is arranged in a two-dimensional array in a first direction and a second direction intersecting the first direction;
a first signal line connected to the pixel circuit continuous in the second direction; and
a first signal processing circuit configured to perform signal processing on a signal from the pixel circuit output from a plurality of the signal lines, in which
each of at least one transistor in the pixel circuit and at least one transistor in the first signal processing circuit is a three-dimensional transistor.
   (2)

The solid-state imaging device according to (1), in which
the three-dimensional transistor
includes a gate electrode including a first vertical gate electrode and a second vertical gate electrode that are embedded in a depth direction from a substrate surface of a semiconductor substrate,
each of the first vertical gate electrode and the second vertical gate electrode has a structure in which a second electrode width at a second depth from the substrate surface is shorter than a first electrode width at a first depth from the substrate surface,
the first depth is a position of a channel uppermost surface of a channel region between the first vertical gate electrode and the second vertical gate electrode, the channel uppermost surface being closest to the substrate surface,
the second depth is a position of a vertical gate electrode bottom surface farthest from the substrate surface in the first vertical gate electrode and the second vertical gate electrode, and
directions of the first electrode width and the second electrode width are same as a direction of a channel width of the channel region.
   (3)

The solid-state imaging device according to (1) or (2), in which
a negative potential is applied to a well region of a plurality of the three-dimensional transistors.
   (4)

The solid-state imaging device according to any one of (1) to (3), further including:
a first substrate on which at least the pixel circuit and the first signal processing circuit are formed; and
a second substrate on which at least a second signal processing circuit connected to the first signal processing circuit via a second signal line is formed, in which
the first substrate and the second substrate are stacked to be formed.
   (5)

The solid-state imaging device according to (4), in which
the three-dimensional transistor is formed in the first substrate.
   (6)

The solid-state imaging device according to (4) or (5), in which
the first signal processing circuit includes:
a load transistor through which a current according to a bias voltage flows.
   (7)

The solid-state imaging device according to (6), in which
the load transistor is formed by the three-dimensional transistor.
   (8)

The solid-state imaging device according to (6) or (7), in which
a capacitor connected to a gate of the load transistor is formed by the three-dimensional transistor.
   (9)

The solid-state imaging device according to any one of (6) to (8), in which
a transistor that selects a capacitor connected to a gate of the load transistor is formed by the three-dimensional transistor.
   (10)

The solid-state imaging device according to any one of (6) to (9), in which
a transistor connected to a gate voltage of the load transistor is formed by the three-dimensional transistor.
   (11)

The solid-state imaging device according to any one of (1) to (3), in which
the first signal processing circuit includes:
a transistor that is connected to the first signal line and forms a differential pair that receives a reference signal and a signal output from the first signal line.
   (12)

The solid-state imaging device according to (11), in which
the transistor forming the differential pair is formed by the three-dimensional transistor.
   (13)

The solid-state imaging device according to (11) or (12), in which
the first signal processing circuit includes:
a load transistor that is connected to a transistor forming the differential pair and through which a current according to a bias voltage flows.
   (14)

The solid-state imaging device according to (13), in which
the load transistor is formed by the three-dimensional transistor.
   (15)

The solid-state imaging device according to (13) or (14), in which
a transistor connected to a gate of the load transistor is formed by the three-dimensional transistor.
   (16)

A manufacturing method for a semiconductor device, the semiconductor device including:
a pixel circuit configured to output a signal based on intensity of light received by a light receiving element;
a pixel array in which the pixel circuit is arranged in a two-dimensional array in a first direction and a second direction intersecting the first direction;
a signal line connected to the pixel circuit continuous in the second direction; and
a selector configured to select a signal from the pixel circuit output from a plurality of the signal lines,
each of at least one transistor in the pixel circuit and at least one transistor in the selector is a three-dimensional transistor,
the manufacturing method including:
forming the three-dimensional transistor in the pixel circuit and the three-dimensional transistor in the selector in a same step.
   (17)

The manufacturing method for the semiconductor device according to (16), in which
the three-dimensional transistor
includes a gate electrode including a first vertical gate electrode and a second vertical gate electrode that are embedded in a depth direction from a substrate surface of a semiconductor substrate,
each of the first vertical gate electrode and the second vertical gate electrode has a structure in which a second electrode width at a second depth from the substrate surface is shorter than a first electrode width at a first depth from the substrate surface,
the first depth is a position of a channel uppermost surface of a channel region between the first vertical gate electrode and the second vertical gate electrode, the channel uppermost surface being closest to the substrate surface,
the second depth is a position of a vertical gate electrode bottom surface farthest from the substrate surface in the first vertical gate electrode and the second vertical gate electrode, and
directions of the first electrode width and the second electrode width are same as a direction of a channel width of the channel region.

Aspects of the present disclosure are not limited to the above-described embodiments, and include various conceivable modifications. The effects of the present disclosure are not limited to the above-described contents. The components in each of the embodiments may be appropriately combined and applied. That is, various additions, modifications, and partial deletions can be made without departing from the conceptual idea and gist of the present disclosure derived from the contents defined in the claims and equivalents and the like thereof.

### REFERENCE SIGNS LIST

1 Solid-state imaging device
10 Pixel array
100 Pixel circuit
12 Vertical drive circuit
120 Line direction signal line
14 Horizontal drive circuit
140 Column direction signal line
16 First signal processing circuit
160 First signal line
18 Second signal processing circuit
180 Second signal line
182 Comparison voltage generation circuit
2 Semiconductor substrate
20 First substrate
22 Second substrate
200 Light receiving region
202 First signal processing region
204 First connection region
206 Second connection region
208 Second signal processing region
210 Logic circuit region
M01, M02, M03, M04, M05, M06, M07, M08, M09, M10, M11,
M12, M13, M14, M15 Transistor
P Light receiving element
C01, C02, C03 Capacitor

1. A solid-state imaging device comprising:
a pixel circuit configured to output a signal based on intensity of light received by a light receiving element;
a pixel array in which the pixel circuit is arranged in a two-dimensional array in a first direction and a second direction intersecting the first direction;
a first signal line connected to the pixel circuit continuous in the second direction; and
a first signal processing circuit configured to perform signal processing on a signal from the pixel circuit output from a plurality of the signal lines, wherein
each of at least one transistor in the pixel circuit and at least one transistor in the first signal processing circuit is a three-dimensional transistor.

2. The solid-state imaging device according to claim 1, wherein
the three-dimensional transistor
includes a gate electrode including a first vertical gate electrode and a second vertical gate electrode that are embedded in a depth direction from a substrate surface of a semiconductor substrate,
each of the first vertical gate electrode and the second vertical gate electrode has a structure in which a second electrode width at a second depth from the substrate surface is shorter than a first electrode width at a first depth from the substrate surface,
the first depth is a position of a channel uppermost surface of a channel region between the first vertical gate electrode and the second vertical gate electrode, the channel uppermost surface being closest to the substrate surface,
the second depth is a position of a vertical gate electrode bottom surface farthest from the substrate surface in the first vertical gate electrode and the second vertical gate electrode, and
directions of the first electrode width and the second electrode width are same as a direction of a channel width of the channel region.

3. The solid-state imaging device according to claim 1, wherein
a negative potential is applied to a well region of a plurality of the three-dimensional transistors.

4. The solid-state imaging device according to claim 1, further comprising:
a first substrate on which at least the pixel circuit and the first signal processing circuit are formed; and
a second substrate on which at least a second signal processing circuit connected to the first signal processing circuit via a second signal line is formed, wherein
the first substrate and the second substrate are stacked to be formed.

5. The solid-state imaging device according to claim 4, wherein
the three-dimensional transistor is formed in the first substrate.

6. The solid-state imaging device according to claim 4, wherein
the first signal processing circuit includes:
a load transistor through which a current according to a bias voltage flows.

7. The solid-state imaging device according to claim 6, wherein
the load transistor is formed by the three-dimensional transistor.

8. The solid-state imaging device according to claim 6, wherein
a capacitor connected to a gate of the load transistor is formed by the three-dimensional transistor.

9. The solid-state imaging device according to claim 6, wherein
a transistor that selects a capacitor connected to a gate of the load transistor is formed by the three-dimensional transistor.

10. The solid-state imaging device according to claim 6, wherein
a transistor connected to a gate voltage of the load transistor is formed by the three-dimensional transistor.

11. The solid-state imaging device according to claim 1, wherein
the first signal processing circuit includes:
a transistor that is connected to the first signal line and forms a differential pair that receives a reference signal and a signal output from the first signal line.

12. The solid-state imaging device according to claim 11, wherein
the transistor forming the differential pair is formed by the three-dimensional transistor.

13. The solid-state imaging device according to claim 11, wherein
the first signal processing circuit includes:
a load transistor that is connected to a transistor forming the differential pair and through which a current according to a bias voltage flows.

14. The solid-state imaging device according to claim 13, wherein
the load transistor is formed by the three-dimensional transistor.

15. The solid-state imaging device according to claim 13, wherein
a transistor connected to a gate of the load transistor is formed by the three-dimensional transistor.

16. A manufacturing method for a semiconductor device, the semiconductor device comprising:
a pixel circuit configured to output a signal based on intensity of light received by a light receiving element;
a pixel array in which the pixel circuit is arranged in a two-dimensional array in a first direction and a second direction intersecting the first direction;
a signal line connected to the pixel circuit continuous in the second direction; and
a selector configured to select a signal from the pixel circuit output from a plurality of the signal lines, wherein
each of at least one transistor in the pixel circuit and at least one transistor in the selector is a three-dimensional transistor,
the manufacturing method comprising:
forming the three-dimensional transistor in the pixel circuit and the three-dimensional transistor in the selector in a same step.

17. The manufacturing method for the semiconductor device according to claim 16, wherein
the three-dimensional transistor
includes a gate electrode including a first vertical gate electrode and a second vertical gate electrode that are embedded in a depth direction from a substrate surface of a semiconductor substrate,
each of the first vertical gate electrode and the second vertical gate electrode has a structure in which a second electrode width at a second depth from the substrate surface is shorter than a first electrode width at a first depth from the substrate surface,
the first depth is a position of a channel uppermost surface of a channel region between the first vertical gate electrode and the second vertical gate electrode, the channel uppermost surface being closest to the substrate surface,
the second depth is a position of a vertical gate electrode bottom surface farthest from the substrate surface in the first vertical gate electrode and the second vertical gate electrode, and
directions of the first electrode width and the second electrode width are same as a direction of a channel width of the channel region.
